(19) United States
(12) Patent Application Publication
(10) Pub. No.: US 2024/0429031 A1
(43) Pub. Date: Dec. 26, 2024

(54) ALUMINA CERAMIC MEMBER, METHOD FOR MANUFACTURING ALUMINA CERAMIC MEMBER, COMPONENT FOR SEMICONDUCTOR MANUFACTURING APPARATUS, AND SUBSTRATE PROCESSING APPARATUS

(71) Applicants: Tokyo Electron Limited, Tokyo (JP); Nagoya Institute of Technology, Aichi (JP)

(72) Inventors: Masanori SATO, Miyagi (JP); Atsushi KAWABATA, Miyagi (JP); Ryusei KASHIMURA, Miyagi (JP); Jun HIROSE, Miyagi (JP); Kunihiko KATO, Aichi (JP); Takashi SHIRAI, Gifu (JP)

(21) Appl. No.: 18/824,128

(22) Filed: Sep. 4, 2024

Related U.S. Application Data
(63) Continuation of application No. PCT/JP2023/008509, filed on Mar. 7, 2023.

(30) Foreign Application Priority Data
Mar. 11, 2022 (JP) 2022-038476

(51) Int. Cl. H01J 37/32; H01J 9/00

(52) U.S. Cl. CPC H01J 37/32715; H01J 9/00; H01J 37/32467

(57) ABSTRACT

An alumina ceramic member contains an alumina polycrystal with an average grain size less than or equal to 100 μm. The alumina ceramic member is doped with yttrium in a state other than a crystalline state of an oxide, a crystalline state of a garnet structure, or an amorphous state, at grain boundaries of the alumina polycrystal.

### CROSS-REFERENCE TO RELATED APPLICATIONS

This application is a continuation application of International Application No. PCT/JP2023/008509 filed on Mar. 7, 2023, and designating the U.S., which is based upon and claims priority to Japanese Patent Application No. 2022-038476 filed on Mar. 11, 2022, the entire contents of which are incorporated herein by reference.

### TECHNICAL FIELD

The present disclosure relates to an alumina ceramic member, a method for manufacturing an alumina ceramic member, a component for a semiconductor manufacturing apparatus, and a substrate processing apparatus.

### BACKGROUND

Patent Literature 1 describes an electrostatic chuck (ESC) formed from a sintered material of alumina or yttria.

### CITATION LIST

### Patent Literature

Patent Literature 1: Japanese Unexamined Patent Application Publication No. 2019-21708

### SUMMARY

An alumina ceramic member according to one aspect of the present disclosure contains an alumina polycrystal with an average grain size less than or equal to 100 μm and is doped with yttrium in a state other than a crystalline state of an oxide, a crystalline state of a garnet structure, or an amorphous state, at grain boundaries of the alumina polycrystal.

### BRIEF DESCRIPTION OF DRAWINGS

FIG. 1 is a diagram of a plasma processing system that is an example of a substrate processing apparatus according to the present disclosure;

FIG. 2 is a diagram of a capacitively coupled plasma processing apparatus that is an example of the plasma processing system in FIG. 1;

FIG. 3A is a diagram of an example of an alumina ceramic member (an alumina sintered body doped with 100 ppm of yttrium) according to the present disclosure, FIG. 3B is a diagram of a state of the alumina sintered body in FIG. 3A photographed with an electron microscope, and FIG. 3C is a diagram of a state of the alumina sintered body in FIG. 3A photographed with an optical microscope;

FIG. 4A is a diagram of an example of the alumina ceramic member (an alumina sintered body doped with 200 ppm of yttrium) according to the present disclosure, FIG. 4B is a diagram of a state of the alumina sintered body in FIG. 4A photographed with an electron microscope, and FIG. 4C is a diagram of a state of the alumina sintered body in FIG. 4A photographed with an optical microscope;

FIG. 5A is a diagram of an example of the alumina ceramic member (an alumina sintered body doped with 500 ppm of yttrium) according to the present disclosure, FIG. 5B is a diagram of a state of the alumina sintered body in FIG. 5A photographed with an electron microscope, and FIG. 5C is a diagram of a state of the alumina sintered body in FIG. 5A photographed with an optical microscope;

FIGS. 6A to 6C are diagrams describing an example of the image analysis in a forced grain separation test;

FIG. 7 is a graph indicating the results of the image analysis in the forced grain separation test;

FIG. 8A is a diagram of a state of the example of the alumina ceramic member (the alumina sintered body doped with 100 ppm of yttrium) according to the present disclosure before being polished in the forced grain separation test, FIG. 8B is a diagram of a state of the alumina sintered body in FIG. 8A after being polished, and FIG. 8C is a graph indicating the results of the image analysis in the forced grain separation test;

FIG. 9A is a diagram of a state of the example of the alumina ceramic member (the alumina sintered body doped with 200 ppm of yttrium) according to the present disclosure before being polished in the forced grain separation test, FIG. 9B is a diagram of a state of the alumina sintered body in FIG. 9A after being polished, and FIG. 9C is a graph indicating the results of the image analysis in the forced grain separation test;

FIG. 10A is a diagram of a state of the example of the alumina ceramic member according to the present disclosure (the alumina sintered body doped with 500 ppm of yttrium) before being polished in the forced grain separation test, FIG. 10B is a diagram of a state of the alumina sintered body in FIG. 10A after being polished, and FIG. 10C is a graph indicating the results of the image analysis in the forced grain separation test;

FIG. 11 is a graph indicating the volume resistivity of the alumina ceramic member according to the present disclosure and the volume resistivity of an alumina ceramic member that is not doped with yttrium;

FIG. 12 is a diagram of a state of the alumina ceramic member (alumina sintered body) that is not doped with yttrium photographed with an optical microscope;

FIG. 13 is a diagram of a state of an alumina ceramic member containing YAG (alumina sintered body mixed with 0.02 mass % of solid yttrium nitrate) photographed with an optical microscope; and

FIG. 14A is a diagram of a state of the alumina ceramic member (alumina sintered body) that is not doped with yttrium before being polished in the forced grain separation test, and FIG. 14B is a diagram of a state of the alumina sintered body in FIG. 14A after being polished.

### DESCRIPTION OF THE EMBODIMENTS

The alumina ceramic member according to one aspect of the present disclosure reduces dust generation or grain separation due to friction.

Embodiments of the disclosure will now be described with reference to the drawings as appropriate. Common components in the figures are denoted by the same or corresponding reference symbols and the description thereof may be omitted.

### Alumina Ceramic Member

An alumina ceramic member according to the present disclosure contains an alumina polycrystal with an average grain size less than or equal to 100 μm.

The average grain size herein refers to the diameter of a circle having the same area as an average crystal grain area calculated by microtomy. The average grain size less than or equal to 100 μm refers to an average grain size less than or equal to 100 μm, excluding 0 μm.

Polycrystalline alumina contains many ionic crystals (monocrystalline alumina) gathered together. In each ionic crystal, aluminum ions and oxygen ions, which form alumina (aluminum oxide), are bonded together by ionic bonding. The alumina polycrystal refers to an object of polycrystalline alumina. The crystal structure of the alumina polycrystal is observable by, for example, X-ray diffraction or X-ray scattering.

The alumina ceramic member according to the present disclosure is doped with yttrium (hereafter also referred to as Y) at grain boundaries of the alumina polycrystal. The grain boundaries of the alumina polycrystal herein refer to interfaces between crystals in the alumina polycrystal. Doping refers to adding yttrium to the alumina polycrystal as a dopant.

The alumina ceramic member according to the present disclosure is doped with yttrium in a state other than a crystalline state of an oxide, a crystalline state of a garnet structure, or an amorphous state, at the grain boundaries of the alumina polycrystal.

Yttrium in a crystalline state of an oxide refers to yttrium in a crystalline state of yttrium oxide (yttria). Yttrium in a crystalline state of a garnet structure refers to yttrium in a crystalline state of a garnet structure (yttrium aluminum garnet, or YAG) of yttrium aluminum complex oxide. Yttrium in an amorphous state refers to, in addition to a fully amorphous state containing yttrium, a state in which amorphous components containing yttrium relatively outnumber crystalline components containing yttrium.

In the present disclosure, the state other than the crystalline state of an oxide, the crystalline state of a garnet structure, or the amorphous state is specifically an ionic state. In other words, the alumina ceramic member according to the present disclosure is doped with yttrium in the ionic state in the alumina polycrystal. More specifically, some aluminum ions in the alumina polycrystal are selectively substituted by yttrium ions.

Doped Yttrium at the grain boundaries of the alumina polycrystal being in the ionic state can be determined based on whether yttria, YAG, or the amorphous state is identified in the alumina ceramic member. More specifically, when YAG, yttrium, and the amorphous state are not detected in the alumina ceramic member, yttrium in the alumina polycrystal may be in the ionic state. When YAG, yttria, or the amorphous state is detected, yttrium in the alumina polycrystal may be YAG or yttria or in the amorphous state.

X-ray diffraction or X-ray scattering may be used to analyze whether yttria, YAG, or the amorphous state is identified in the alumina ceramic member. The content rate of Y in the alumina ceramic member may be detected by glow discharge mass spectrometry (GDMS) to determine whether yttrium is in the ionic state.

For example, yttria, YAG, or the amorphous state in the alumina polycrystal forms a different phase that wears more easily than alumina. Thus, when no different phase other than the alumina polycrystal (corundum) is detected by X-ray diffraction or X-ray scattering, yttrium is determined not to be yttria, YAG, or in the amorphous state (determined to be in the ionic state).

Some aluminum ions in the alumina polycrystal being selectively substituted by the yttrium ions is determined by, for example, scanning electron microscopy with energy dispersive X-ray spectroscopy (SEM-EDX), scanning electron microscopy with electron probe microanalyzer (SEM-EPMA), high angle annular dark-field scanning transmission electron microscopy (HAADF-STEM), transmission electron microscopy with energy dispersive X-ray spectroscopy (TEM-EDS), electron energy loss spectroscopy (EELS), or secondary-ion mass spectrometry (SIMS).

For example, no different phase resulting from segregation of yttrium in the alumina polycrystal indicates that some aluminum ions in the alumina polycrystal are selectively substituted by the yttrium ions. A different phase resulting from segregation of yttrium can be determined by analyzing whether yttrium is identified in the alumina polycrystal by SEM-EDX or SEM-EPMA.

More specifically, when yttrium is not detected in the alumina polycrystal by SEM-EDX or SEM-EPMA, no different phase results from segregation of yttrium. Thus, some aluminum ions in the alumina polycrystal are determined to be selectively substituted by the yttrium ions.

The grain boundaries are observable by HAADF-STEM. Yttrium (Y) atoms heavier than aluminum (Al) atoms are bright in the observation. Yttrium (Y) atoms bonding to each other in the atomic arrangement of alumina (Al₂O₃) are observable by TEM-EDS or EELS. The sites of the Al ions in Al₂O₃ substituted by the Y ions are observable with a combination of these methods, and Y in the ionic state in Al₂O₃ is thus determined.

The alumina ceramic member according to the present disclosure, as described above is doped with yttrium in the state other than the crystalline state of an oxide, the crystalline state of a garnet structure, or the amorphous state, at the grain boundaries of the alumina polycrystal with an average grain size less than or equal to 100 μm. More specifically, at the grain boundaries of the alumina polycrystal, doped yttrium is not yttria or YAG or not in the amorphous state, but is in an ionic state of yttrium ions by which some aluminum ions are selectively substituted.

This strengthens the grain boundary bonding in the alumina polycrystal, thus reducing dust generation or grain separation due to friction. The reduced dust generation or the reduced grain separation due to friction may allow the structure to have higher plasma resistance and higher corrosion resistance to gas.

In the alumina ceramic member according to the present disclosure, the doping amount of yttrium is not particularly limited. The doping amount of yttrium is preferably adjusted based on the average grain size of the alumina polycrystal.

For example, for the alumina polycrystal with an average grain size of 1 μm, the doping amount of yttrium in the alumina polycrystal is preferably 100 ppm or greater and 1000 ppm or less, more preferably 100 ppm or greater and 800 ppm or less, and still more preferably 400 ppm or greater and 700 ppm or less.

For the alumina polycrystal with an average grain size of 10 μm, the doping amount of yttrium in the alumina polycrystal is preferably 10 ppm or greater and 100 ppm or less, more preferably 10 ppm or greater and 80 ppm or less, and still preferably 40 ppm or greater and 70 ppm or less.

For the alumina polycrystal with an average grain size of 100 μm, the doping amount of yttrium in the alumina polycrystal is preferably 1 ppm or greater and 10 ppm or less, more preferably 1 ppm or greater and 8 ppm or less, and still preferably 4 ppm or greater and 7 ppm or less.

In the alumina ceramic member according to the present disclosure, as described above, the doping amount of yttrium is adjusted based on the average grain size of the alumina polycrystal, thus further strengthening the grain boundary bonding in the alumina polycrystal. This further reduces dust generation or grain separation due to friction. Although the range of the doping amount of yttrium in the alumina polycrystal with the average grain size fixed to 1 μm, 10 μm, and 100 μm is described in the embodiments of the present disclosure, the average grain size of the alumina polycrystal is not limited to these numerical values.

The alumina ceramic member according to the present disclosure may have any physical properties, but a volume resistivity at 200° C. is preferably greater than or equal to 1.0×10¹⁵ Ωcm, more preferably greater than or equal to 5.0×10¹⁵ Ωcm, or still more preferably greater than or equal to 1.0×10¹⁶ Ωcm.

For the alumina ceramic member according to the present disclosure having a volume resistivity greater than or equal to 1.0×10¹⁵ Ωcm at 200° C. as described above, the alumina polycrystal doped with yttrium as described above has a uniform crystal structure, thus further reducing dust generation or grain separation due to friction.

### Method for Manufacturing an Alumina Ceramic Member

A method for manufacturing an alumina ceramic member according to the present disclosure is a method for manufacturing the alumina ceramic member according to the present disclosure described above. In other words, the alumina ceramic member manufactured with the manufacturing method according to the present disclosure contains the alumina polycrystal with an average grain size less than or equal to 100 μm and is doped with yttrium in the state (e.g., the ionic state) other than the crystalline state of an oxide, the crystalline state of a garnet structure, or the amorphous state, at the grain boundaries of the alumina polycrystal.

The method for manufacturing the alumina ceramic member according to the present disclosure includes adding alumina to an aqueous solution of yttrium and mixing the aqueous solution. More specifically, a solution (hereafter referred to as an yttrium nitrate solution) is prepared by dissolving yttrium nitrate hexahydrate (Y(NO₃)₃·6H₂O) in water and adjusting the resultant water to 1 μmol to 10 mmol.

Yttrium nitrate dissolved in water is not limited to a hydrate, and may be an anhydride. When yttrium nitrate dissolved in water is a hydrate, yttrium nitrate is not limited to a hexahydrate and may be an n-hydrate (n is an integer greater than or equal to 2 excluding 6).

The concentration of the yttrium nitrate solution may be appropriately adjusted based on the doping amount of yttrium in the alumina polycrystal. For example, when 100 g of alumina is mixed with the yttrium nitrate solution as described later, 2000 ml of yttrium nitrate solution with a concentration of 0.004 mol/L is used.

Powder alumina is added to the prepared yttrium nitrate solution and stirred. The stirring conditions may be, but not limited to, the stirring temperature of 3° C. to 50° C. and the stirring time of 5 minutes to 48 hours.

After stirring, a solid content resulting from solid-liquid separation of a mixed slurry of alumina and yttrium nitrate is left at rest and dried. The drying conditions are preferably, but not limited to, the drying time of 12 to 120 hours and the dry method of lyophilization.

After drying, the resultant dried solid content is sintered. The sintering conditions may be any conditions, and are, for example, the heating temperature of 1200° C. to 1500° C., the heating speed of 1° C. to 10° C./minute, the heating time of 10 minutes to 2 hours, the applied pressure of 80 MPa, and the pressure applying onset temperature of 1250° C. The sintering method is, for example, pulse electric current sintering (PECS).

The method for manufacturing the alumina ceramic member according to the present disclosure includes adding alumina to the aqueous solution of yttrium and mixing the aqueous solution as described above, thus reducing coarse grains in the stirring and mixing process. Thus, the alumina ceramic member obtained as a sintered body can reduce dust generation or grain separation due to friction.

As described above, the resultant mixed slurry is lyophilized and thus prevented from aggregating in the drying process. This reduces segregation of the dopant in the drying process. The alumina ceramic member obtained as a sintered body can thus reduce dust generation or grain separation due to friction.

The sintering method of delaying the start time of applying pressure allows, for example, carbon from the slurry to sublimate before sintering. This allows components other than yttrium that are impurities in the alumina polycrystal to be removed before sintering, thus preventing the obtained sintered body from having a lower strength.

### Component for Semiconductor Manufacturing Apparatus

A component for a semiconductor manufacturing apparatus according to the present disclosure is formed of the alumina ceramic member according to the present disclosure described above. In other words, the alumina ceramic member used for the component for the semiconductor manufacturing apparatus contains the alumina polycrystal with an average grain size less than or equal to 100 μm and is doped with yttrium in the state (e.g., the ionic state) other than the crystalline state of an oxide, the crystalline state of a garnet structure, or the amorphous state, at the grain boundaries of the alumina polycrystal. The component for the semiconductor manufacturing apparatus is a component used in a semiconductor manufacturing apparatus.

The alumina ceramic member described above is doped with yttrium in the state other than the crystalline state of an oxide, the crystalline state of a garnet structure, or the amorphous state, at the grain boundaries of the alumina polycrystal with an average grain size less than or equal to 100 μm, thus reducing dust generation or grain separation due to friction. This may allow the alumina ceramic member to have higher plasma resistance and higher corrosion resistance to gas.

The component for the semiconductor manufacturing apparatus according to the present disclosure can thus reduce dust generation or grain separation due to friction similarly to the alumina ceramic member according to the present disclosure, and thus has plasma resistance and corrosion resistance to gas as a component used in a semiconductor manufacturing apparatus.

The component for the semiconductor manufacturing apparatus according to the present disclosure having plasma resistance and corrosion resistance to gas can be used as, for example, an electrostatic chuck (ESC), a pick, a rocket, a lifter pin, a wall, or a buckle. The component for the semiconductor manufacturing apparatus according to the present disclosure that is used as an ECS of the above components can reduce dust generation or grain separation from friction, and is thus more effective.

### Substrate Processing Apparatus

A substrate processing apparatus according to the present disclosure processes a substrate. The substrate processing apparatus includes a substrate support having a substrate support surface for supporting the substrate. The substrate support is formed of the alumina ceramic member according to the present disclosure described above. The substrate processing apparatus according to the present disclosure will now be described with reference to the drawings.

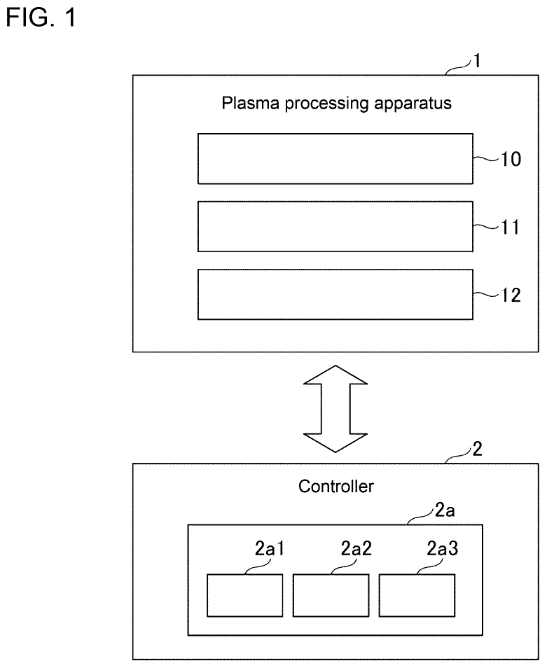

FIG. 1 is a diagram of a plasma processing system that is an example of the substrate processing apparatus according to the present disclosure. In the present embodiment, the plasma processing system includes a plasma processing apparatus 1 and a controller 2.

The plasma processing apparatus 1 includes a plasma processing chamber 10, a substrate support 11, and a plasma generator 12.

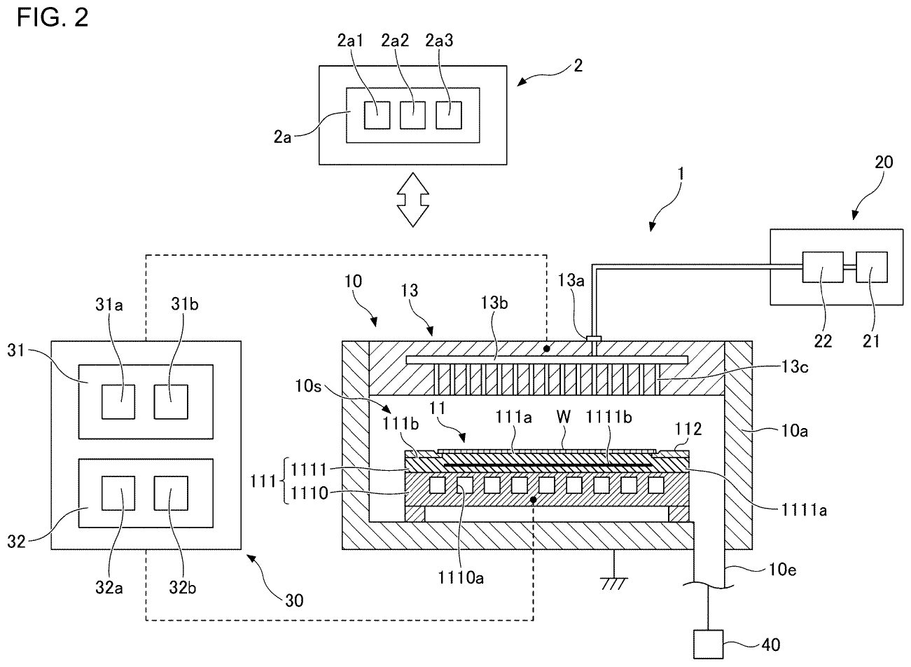

The plasma processing chamber 10 has a plasma processing space. The plasma processing chamber 10 also has at least one gas inlet for supplying at least one process gas into the plasma processing space and at least one gas outlet for discharging the gas from the plasma processing space. The gas inlet is connected to a gas supply 20 described later, and the gas outlet is connected to an exhaust system 40 described later (FIG. 2).

The substrate support 11 is located in the plasma processing space and has a substrate support surface for supporting a substrate.

The plasma generator 12 generates plasma from at least one process gas supplied into the plasma processing space. The plasma generated in the plasma processing space may be, for example, capacitively coupled plasma (CCP), inductively coupled plasma (ICP), electron cyclotron resonance (ECR) plasma, helicon wave plasma (HWP), or surface wave plasma (SWP).

Various plasma generators including an alternating current (AC) plasma generator and a direct current (DC) plasma generator may be used. In the present embodiment, an AC signal (AC power) used in the AC plasma generator has a frequency in a range of 100 kHz to 10 GHz. Thus, the AC signal includes a radio-frequency (RF) signal and a microwave signal. In the present embodiment, the RF signal has a frequency in a range of 100 kHz to 150 MHz.

The controller 2 processes computer-executable instructions that cause the plasma processing apparatus 1 to perform various steps described in the present disclosure. The controller 2 may control the components of the plasma processing apparatus 1 to perform the various steps described herein. In the present embodiment, some or all of the components of the controller 2 may be included in the plasma processing apparatus 1. The controller 2 may include a processor 2a1, a storage 2a2, and a communication interface 2a3 included in a computer 2a.

The controller 2 is implemented by, for example, the computer 2a. The processor 2a1 may perform various control operations by loading a program from the storage 2a2 and executing the loaded program. The program may be prestored in the storage 2a2 or may be obtained through a medium as appropriate. The obtained program is stored into the storage 2a2 to be loaded from the storage 2a2 and executed by the processor 2a1.

The medium may be one of various storage media readable by the computer 2a, or a communication line connected to the communication interface 2a3. The processor 2a1 may be a central processing unit (CPU).

The storage 2a2 may include a random-access memory (RAM), a read-only memory (ROM), a hard disk drive (HDD), a solid-state drive (SSD), or a combination of these. The communication interface 2a3 may communicate with the plasma processing apparatus 1 through a communication line, such as a local area network (LAN).

A capacitively coupled plasma processing apparatus that is an example of the plasma processing system described above will now be described. FIG. 2 illustrates an example structure of the capacitively coupled plasma processing apparatus.

The capacitively coupled plasma processing apparatus 1 includes the plasma processing chamber 10, the gas supply 20, a power supply 30, and the exhaust system 40. The plasma processing apparatus 1 also includes the substrate support 11 and a gas inlet section. The gas inlet section allows at least one process gas to be introduced into the plasma processing chamber 10. The gas inlet section includes a shower head 13.

The substrate support 11 is located in the plasma processing chamber 10. The shower head 13 is located above the substrate support 11. In the present embodiment, the shower head 13 defines at least a part of the ceiling of the plasma processing chamber 10.

The plasma processing chamber 10 has a plasma processing space 10s defined by the shower head 13, a side wall 10a of the plasma processing chamber 10, and the substrate support 11. The plasma processing chamber 10 is grounded. The shower head 13 and the substrate support 11 are electrically insulated from the housing of the plasma processing chamber 10.

The substrate support 11 includes a body 111 and a ring assembly 112. The body 111 includes a central portion 111a for supporting a substrate W and an annular portion 111b for supporting the ring assembly 112. The substrate W is, for example, a wafer. The annular portion 111b of the body 111 surrounds the central portion 111a of the body 111 as viewed in plan view.

The substrate W is placed on the central portion 111a of the body 111. The ring assembly 112 is placed on the annular portion 111b of the body 111 to surround the substrate W on the central portion 111a of the body 111. The central portion 111a is also referred to as the substrate support surface for supporting the substrate W. The annular portion 1l1b is also referred to as a ring support surface for supporting the ring assembly 112.

In the present embodiment, the body 111 includes a base 1110 and an ESC 1111. The base 1110 includes a conductive member. The conductive member in the base 1110 may serve as a lower electrode.

The ESC 1111 is located on the base 1110. The ESC 1111 includes a ceramic member 1111a and an electrostatic electrode 1111b inside the ceramic member 1111a. The ceramic member 1111a includes the central portion 111a. In the present embodiment, the ceramic member 1111a also includes the annular portion 1l1b.

The annular portion 111b may be included in a separate member surrounding the ESC 1111, such as an annular ESC or an annular insulating member. In this case, the ring assembly 112 may be located on the annular ESC or the annular insulating member, or may be located on both the ESC 1111 and the annular insulating member.

At least one RF/DC electrode coupled to an RF power supply 31 (described later), a DC power supply 32 (described later), or both may be located inside the ceramic member 1111a. In this case, the at least one RF/DC electrode serves as the lower electrode. When a bias RF signal, a DC signal (described later), or both are provided to at least one RF/DC electrode, the at least one RF/DC electrode is also referred to as a bias electrode.

The conductive member in the base 1110 and the at least one RF/DC electrode may serve as multiple lower electrodes. The electrostatic electrode 1111b may also serve as a lower electrode. Thus, the substrate support 11 includes at least one lower electrode.

The ring assembly 112 includes one or more annular members. In the present embodiment, one or more annular members include one or more edge rings and at least one cover ring. The edge ring is formed from a conductive material or an insulating material. The cover ring is formed from an insulating material.

The substrate support 11 may also include a temperature control module that adjusts the temperature of at least one of the ESC 1111, the ring assembly 112, or the substrate to a target temperature. The temperature control module may include a heater, a heat transfer medium, a channel 1110a, or a combination of these. The channel 1110a allows a heat transfer fluid, such as brine or gas, to flow.

In the present embodiment, the channel 1110a is defined in the base 1110, and one or more heaters are located in the ceramic member 1111a in the ESC 1111. The substrate support 11 may include a heat transfer gas supply to supply heat transfer gas into a space between the back surface of the substrate W and the central portion 111a.

In the plasma processing apparatus 1 according to the present embodiment, the component for the semiconductor manufacturing apparatus according to the present disclosure described above is used as the ESC 1111 in the body 111 of the substrate support 11. More specifically, the ESC 1111 included in the plasma processing apparatus 1 according to the present embodiment is formed of the alumina ceramic member according to the present disclosure described above.

More specifically, the alumina ceramic member forming the ESC 111 contains the alumina polycrystal with an average grain size less than or equal to 100 μm and is doped with yttrium in the state (e.g., the ionic state) other than the crystalline state of an oxide, the crystalline state of a garnet structure, or the amorphous state, at the grain boundaries of the alumina polycrystal. The substrate support 11 (more specifically, the ESC 1111) is an example of the substrate support in the substrate processing apparatus according to the present disclosure.

The shower head 13 introduces at least one process gas from the gas supply into the plasma processing space 10s. The shower head 13 has at least one gas inlet 13a, at least one gas-diffusion compartment 13b, and multiple gas guides 13c. The process gas supplied to the gas inlet 13a passes through the gas-diffusion compartment 13b and is introduced into the plasma processing space 10s through the multiple gas guides 13c.

The shower head 13 also includes at least one upper electrode. In addition to the shower head 13, the gas inlet section may include one or more side gas injectors (SGIs) installed in one or more openings in the side wall 10a.

The gas supply 20 may include at least one gas source 21 and at least one flow controller 22. In the present embodiment, the gas supply 20 allows supply of at least one process gas from the corresponding gas source 21 to the shower head 13 through the corresponding flow controller 22.

The flow controller 22 may include, for example, a mass flow controller or a pressure-based flow controller. The gas supply 20 may further include at least one flow rate modulator that allows supply of at least one process gas at a modulated flow rate or in a pulsed manner.

The power supply 30 includes the RF power supply 31 that is coupled to the plasma processing chamber 10 through at least one impedance matching circuit. The RF power supply 31 provides at least one RF signal (RF power) to at least one lower electrode, to at least one upper electrode, or to both the electrodes. This causes plasma to be generated from at least one process gas supplied into the plasma processing space 10s.

The RF power supply 31 may thus at least partially serve as the plasma generator 12. A bias RF signal is provided to at least one lower electrode to generate a bias potential in the substrate W, thus drawing ion components in the plasma to the substrate W.

In the present embodiment, the RF power supply 31 includes a first RF generator 31a and a second RF generator 31b. The first RF generator 31a is coupled to at least one lower electrode, to at least one upper electrode, or to both the electrodes through at least one impedance matching circuit and generates a source RF signal (source RF power) for plasma generation.

In the present embodiment, the source RF signal has a frequency in a range of 10 MHz to 150 MHz. In the present embodiment, the first RF generator 31a may generate multiple source RF signals with different frequencies. The generated source RF signal or the generated multiple source RF signals are provided to at least one lower electrode, to at least one upper electrode, or to both the electrodes.

The second RF generator 31b is coupled to at least one lower electrode through at least one impedance matching circuit and generates a bias RF signal (bias RF power). The frequency of the bias RF signal may be the same as or different from the frequency of the source RF signal.

In the present embodiment, the bias RF signal has a lower frequency than the source RF signal. In the present embodiment, the bias RF signal has a frequency in a range of 100 kHz to 60 MHz.

In the present embodiment, the second RF generator 31b may generate multiple bias RF signals with different frequencies. The generated bias RF signal or the generated multiple bias RF signals are provided to at least one lower electrode. In various embodiments, at least one of the source RF signal or the bias RF signal may be pulsed.

The power supply 30 may include the DC power supply 32 coupled to the plasma processing chamber 10. The DC power supply 32 includes a first DC generator 32a and a second DC generator 32b. In the present embodiment, the first DC generator 32a is coupled to at least one lower electrode and generates a first DC signal. The generated first DC signal is applied to at least one lower electrode.

In the present embodiment, the second DC generator 32b is coupled to at least one upper electrode and generates a second DC signal. The generated second DC signal is applied to at least one upper electrode.

In various embodiments, the first DC signal and the second DC signal may be pulsed. In this case, a sequence of voltage pulses is applied to at least one lower electrode, to at least one upper electrode, or to both the electrodes. The voltage pulses may have a rectangular, trapezoidal, or triangular pulse waveform, or a combination of these pulse waveforms.

In the present embodiment, a waveform generator for generating a sequence of voltage pulses based on DC signals is located between the first DC generator 32a and at least one lower electrode. Thus, the first DC generator 32a and the waveform generator are included in a voltage pulse generator. When the second DC generator 32b and the waveform generator are included in a voltage pulse generator, the voltage pulse generator is coupled to at least one upper electrode.

The voltage pulses may have positive polarity or negative polarity. The sequence of voltage pulses may include one or more positive voltage pulses and one or more negative voltage pulses within one cycle. The first DC generator 32a and the second DC generator 32b may be provided in addition to the RF power supply 31, or the first DC generator 32a may replace the second RF generator 31b.

The exhaust system 40 is connectable to, for example, a gas outlet 10e in the bottom of the plasma processing chamber 10. The exhaust system 40 may include a pressure control valve and a vacuum pump. The pressure control valve regulates the pressure in the plasma processing space 10s. The vacuum pump may include a turbomolecular pump, a dry pump, or a combination of these.

In the substrate processing apparatus (plasma processing apparatus 1) according to the present embodiment, the ESC 1111 is formed of the alumina ceramic member according to the present disclosure as described above. The ESC 1111 can thus reduce dust generation or grain separation due to friction similarly to the alumina ceramic member according to the present disclosure. The plasma processing apparatus 1 according to the present embodiment thus has plasma resistance and corrosion resistance to gas.

The substrate processing apparatus according to the present disclosure is not limited to an apparatus that processes a substrate with plasma, and may be an apparatus that does not use plasma (e.g., an apparatus that processes a substrate with heat).

### EXAMPLES

The alumina ceramic member according to the present disclosure will now be further described in examples. Various tests and evaluation are performed with the method described below. Although the alumina ceramic member is an alumina sintered body in the examples below, the alumina ceramic member according to the present disclosure is not limited to an alumina sintered body, and may be applied to a thermal spray material.

### Example 1

Manufacturing of Alumina Sintered Body (Sample)

To prepare the mixed slurry of alumina and yttrium nitrate, 25 g of powder alumina was added to 500 ml of yttrium nitrate solution adjusted to 2.5 μmol and stirred for 10 minutes at room temperature. The mixed slurry was left at rest for 48 hours. Concentrate obtained by removing supernatant of the mixed slurry was then lyophilized for 48 hours to prepare dry powder. Alumina grains are preferably broken with an ultrasonic generator for 10 to 120 minutes to prepare the mixed slurry.

Yttrium nitrate is a hydrate. Although yttrium nitrate hexahydrate is used in the present example, yttrium nitrate may be any hydrate.

A molded body formed from the dry powder was heated to a temperature of 1250° C. in increments of 5° C./minute. The molded body was further heated to a temperature of 1350° C. in increments of 5° C./minute while receiving 80 MPa of pressure in its thickness direction, and then heated for 20 minutes to obtain an alumina sintered body (sample) doped with 50 ppm of yttrium with respect to the alumina polycrystal. The obtained alumina sintered body has an average grain size less than or equal to 100 μm.

### Determination of Yttrium in the Ionic State

An X-ray diffractometer was used to analyze whether YAG or the amorphous state was identified in the alumina sintered body (sample). When neither YAG nor the amorphous state is detected, yttrium is determined to be in the ionic state. In the alumina sintered body (sample) in Example 1, neither YAG nor the amorphous state was detected, and thus yttrium was determined to be in the ionic state.

### Microstructure Analysis

An optical microscope and an electron microscope were used to capture images of a surface of the obtained alumina sintered body (sample), and the images were observed with naked eyes to analyze the microstructure.

The microstructure analysis was evaluated based on the electron microscope image and the criteria below. The evaluation result represented with A or B was determined positive, whereas the evaluation result represented with C was determined negative. Table 1 indicates the results.
A: Crystals are uniform.
B: Crystals are substantially uniform although coarse grains or segregation is observed.
C: Coarse grains or segregation is observed, and crystals are nonuniform.

### Forced Grain Separation Test

The alumina sintered body (sample) was cut and embedded in resin wax fixed to a sample platform to partly protrude from the resin wax. An image of the portion of the alumina sintered body (sample) protruding from the resin wax before being polished was obtained.

Subsequently, the portion of the alumina sintered body (sample) protruding from the resin wax was mirror polished with a load of 8.4 N/cm² for 15 minutes, and was mechanically polished (final polishing) further with a load of 7.5 N/cm² for 20 minutes, using waterproof sandpaper of #1200 (a particle size of 15.3 μm). The surface of the polished alumina sintered body (sample) was photographed with the electron microscope to obtain an image of the alumina sintered body (sample) after being polished.

An automatic polishing machine (MECATECH234 manufactured by Meiwafosis Co., Ltd.) was used for polishing. The polishing time is predetermined as appropriate, and is, for example, 1 to 50 minutes.

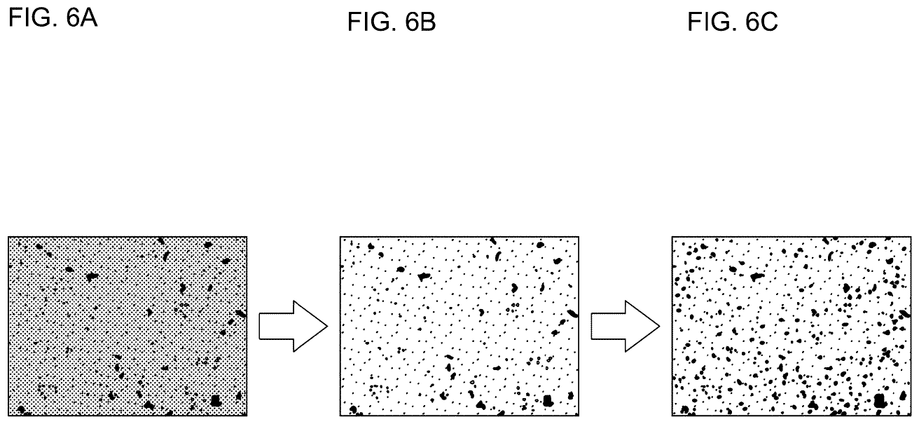

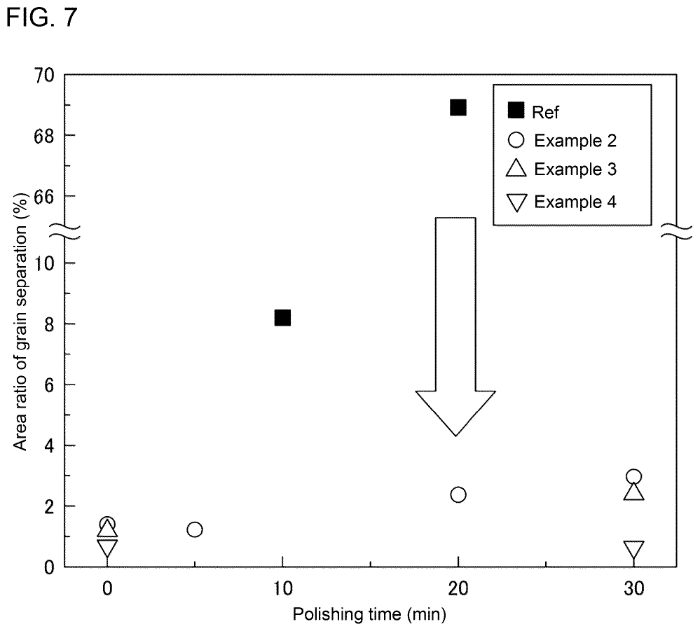

The images obtained before and after polishing were analyzed (FIGS. 6A to 6C) to calculate the area ratio of grain separation for comparison between before and after polishing. A gradient was obtained based on the change in the area ratio of grain separation with respect to the load time (polishing time) for forced grain separation. The likelihood of dust generation (area ratio of grain separation) was determined (FIG. 7) from the obtained gradient and the load of grain separation on a substrate (wafer).

The forced grain separation was evaluated based on the criteria below. The evaluation result represented with A or B was determined positive, whereas the evaluation result represented with C was determined negative. Table 1 indicates the results.
A: The likelihood of dust generation is less than 5%.
B: The likelihood of dust generation is less than 20%.
C: The likelihood of dust generation is greater than or equal to 20%.

### Volume Resistivity

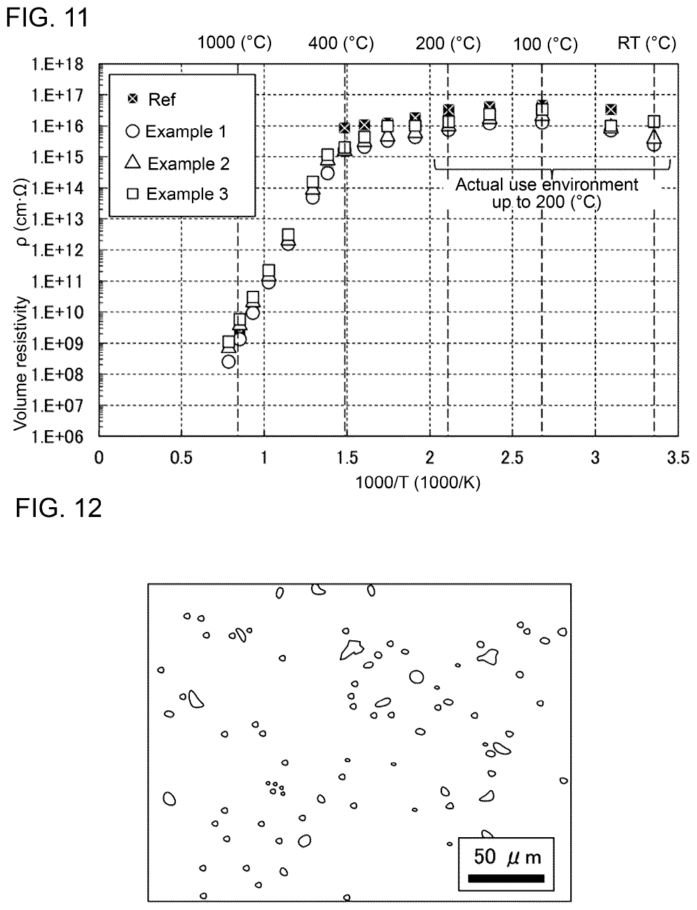

The volume resistivity was measured with a DC three-terminal method complying with JIS C2141. FIG. 11 and Table 1 indicate the results. FIG. 11 and Table 1 indicate that the volume resistivity is greater than or equal to 1.0×10¹⁵ Ωcm in a real use environment of the alumina ceramic member (at room temperature to 200° C.) in Example 1.

### Example 2

An alumina sintered body (sample) was prepared in the same manner as in Example 1 except that 25 g of powder alumina was added to 500 ml of yttrium nitrate solution adjusted to 5 μmol to obtain the alumina sintered body (sample) doped with 100 ppm of yttrium with respect to the alumina polycrystal. The alumina sintered body (sample) was then evaluated. Table 1 indicates the results. In the alumina sintered body (sample) in Example 2, neither YAG nor the amorphous state was detected, and thus yttrium may be in the ionic state.

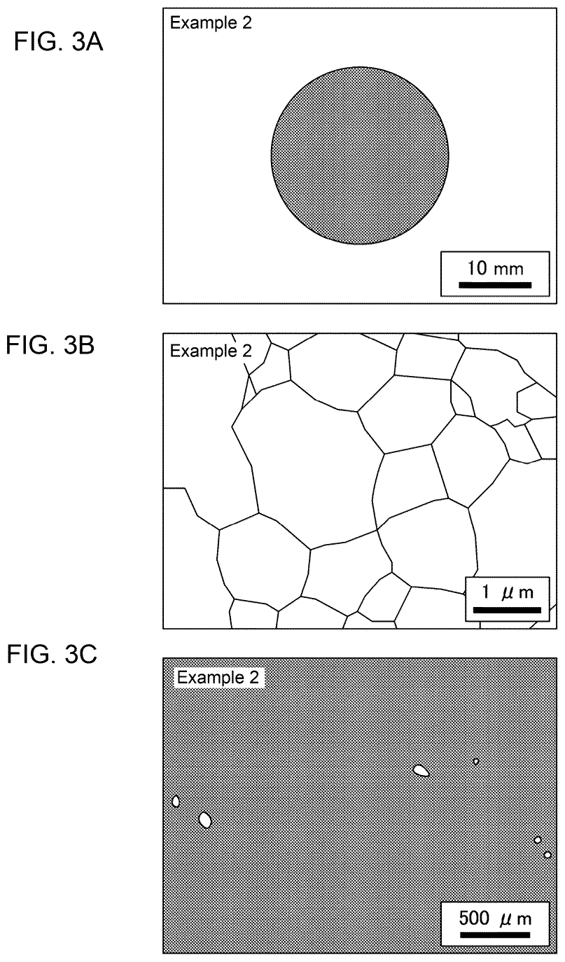

FIG. 3A is a diagram of the alumina sintered body (sample) in Example 2. FIG. 3B is a diagram of an electron microscope image of the alumina sintered body (sample) in Example 2. FIG. 3C is a diagram of an optical microscope image of the alumina sintered body (sample) in Example 2.

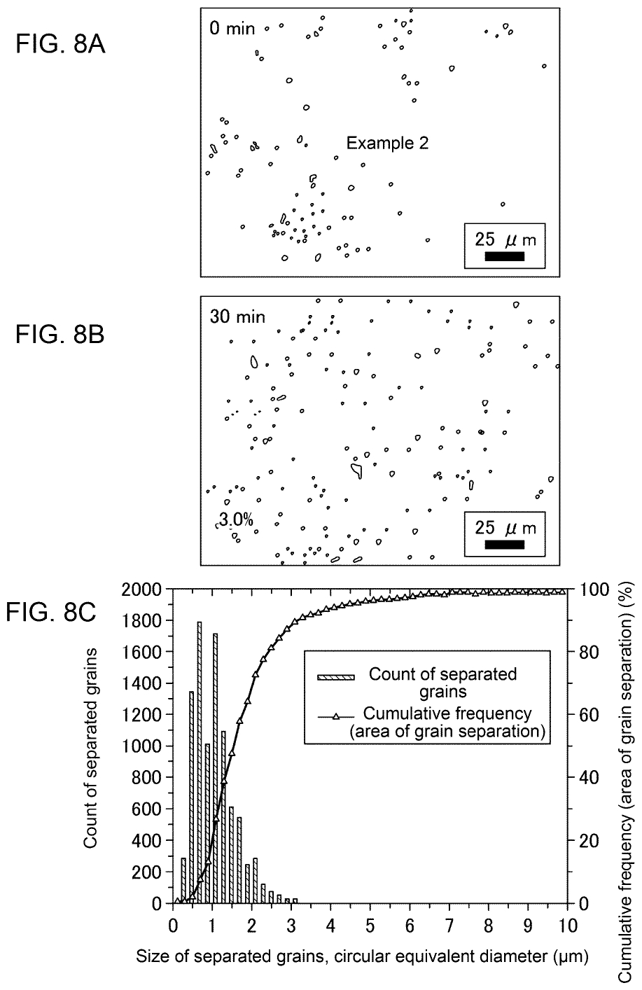

FIG. 8A is a diagram of an optical microscope image of the alumina sintered body (doped with 100 ppm of yttrium) before being polished. FIG. 8B is a diagram of an optical microscope image of the alumina sintered body (sample) after being polished. In the alumina sintered body (sample) after being polished illustrated in FIG. 8B, the likelihood of dust generation is 3.0%.

FIG. 8C is a graph indicating the results of the image analysis in the forced grain separation test. In FIG. 8C, the histogram indicates the relationship between the size of the separated grains (circular equivalent diameter, μm) and the number of separated grains (counts), and the line graph indicates the relationship between the size of the separated grains (circular equivalent diameter, μm) and the area ratio of grain separation (%).

FIG. 11 and Table 1 indicate that the volume resistivity is greater than or equal to 1.0×10¹⁵ in the real use environment of the alumina ceramic member (at room temperature to 200° C.) in Example 2.

### Example 3

An alumina sintered body (sample) was prepared in the same manner as in Example 1 except that 25 g of powder alumina was added to 500 ml of yttrium nitrate solution adjusted to 10 μmol to obtain the alumina sintered body (sample) doped with 200 ppm of yttrium with respect to the alumina polycrystal. The alumina sintered body (sample) was then evaluated. Table 1 indicates the results. In the alumina sintered body (sample) in Example 3, neither YAG nor the amorphous state was detected, and thus yttrium may be in the ionic state.

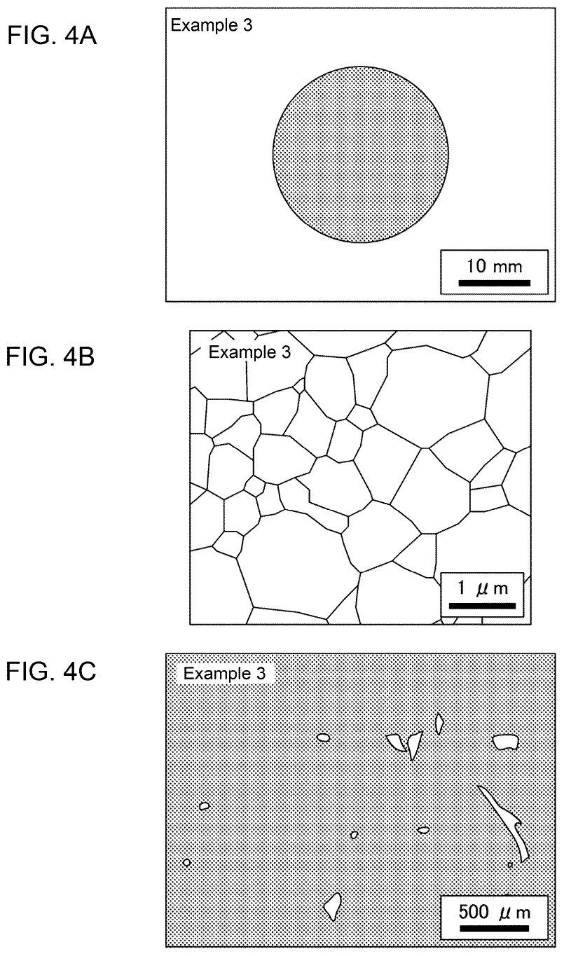

FIG. 4A is a diagram of the alumina sintered body (sample) in Example 3. FIG. 4B is a diagram of an electron microscope image of the alumina sintered body (sample) in Example 3. FIG. 4C is a diagram of an optical microscope image of the alumina sintered body (sample) in Example 3.

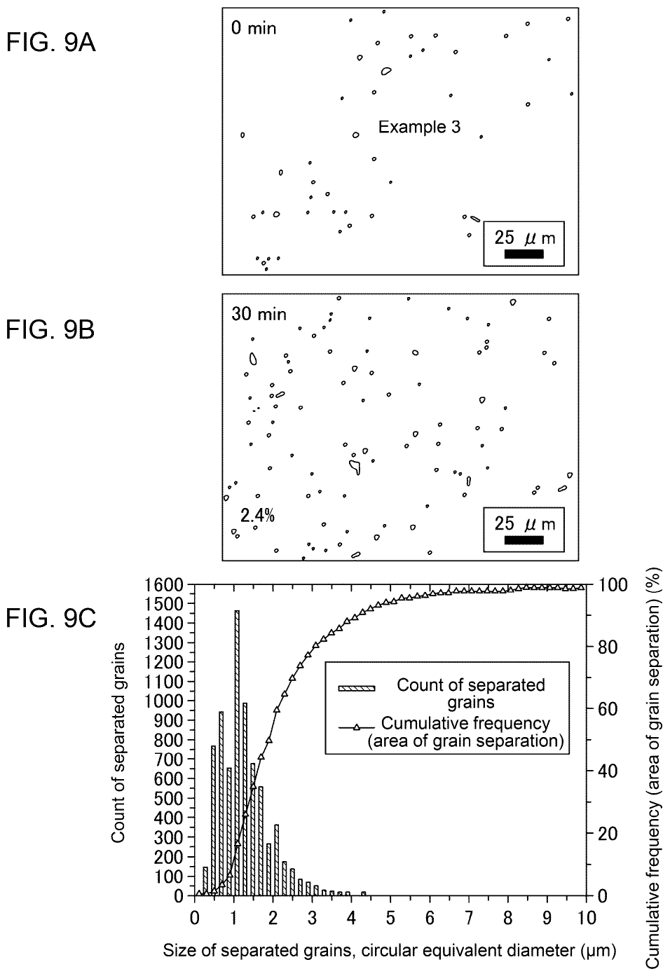

FIG. 9A is a diagram of an optical microscope image of the alumina sintered body (doped with 200 ppm of yttrium) before being polished. FIG. 9B is a diagram of an optical microscope image of the alumina sintered body (sample) after being polished. In the alumina sintered body (sample) after being polished illustrated in FIG. 9B, the likelihood of dust generation is 2.4%.

FIG. 9C is a graph indicating the results of the image analysis in the forced grain separation test. In FIG. 9C, the histogram indicates the relationship between the size of the separated grains (circular equivalent diameter, μm) and the number of separated grains (counts), and the line graph indicates the relationship between the size of the separated grains (circular equivalent diameter, μm) and the area ratio of grain separation (%).

FIG. 11 and Table 1 indicate that the volume resistivity is greater than or equal to 1.0×10¹⁵ in the real use environment of the alumina ceramic member (at room temperature to 200° C.) in Example 3.

### Example 4

An alumina sintered body (sample) was prepared in the same manner as in Example 1 except that 25 g of powder alumina was added to 500 ml of yttrium nitrate solution adjusted to 20 μmol to obtain the alumina sintered body (sample) doped with 500 ppm of yttrium with respect to the alumina polycrystal. The alumina sintered body (sample) was then evaluated. Table 1 indicates the results. In the alumina sintered body (sample) in Example 4, neither YAG nor the amorphous state was detected, and thus yttrium may be in the ionic state.

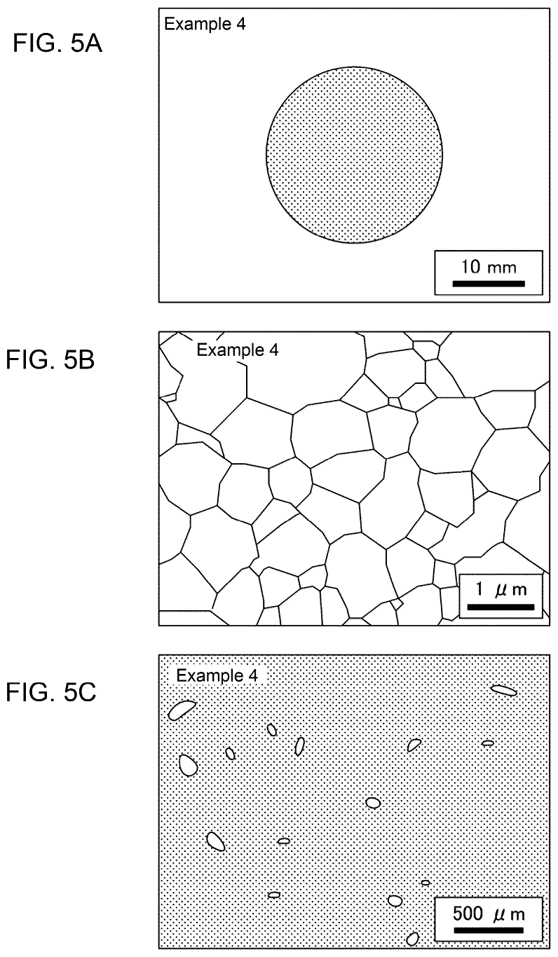

FIG. 5A is a diagram of the alumina sintered body (sample) in Example 4. FIG. 5B is a diagram of an electron microscope image of the alumina sintered body (sample) in Example 4. FIG. 5C is a diagram of an optical microscope image of the alumina sintered body (sample) in Example 4.

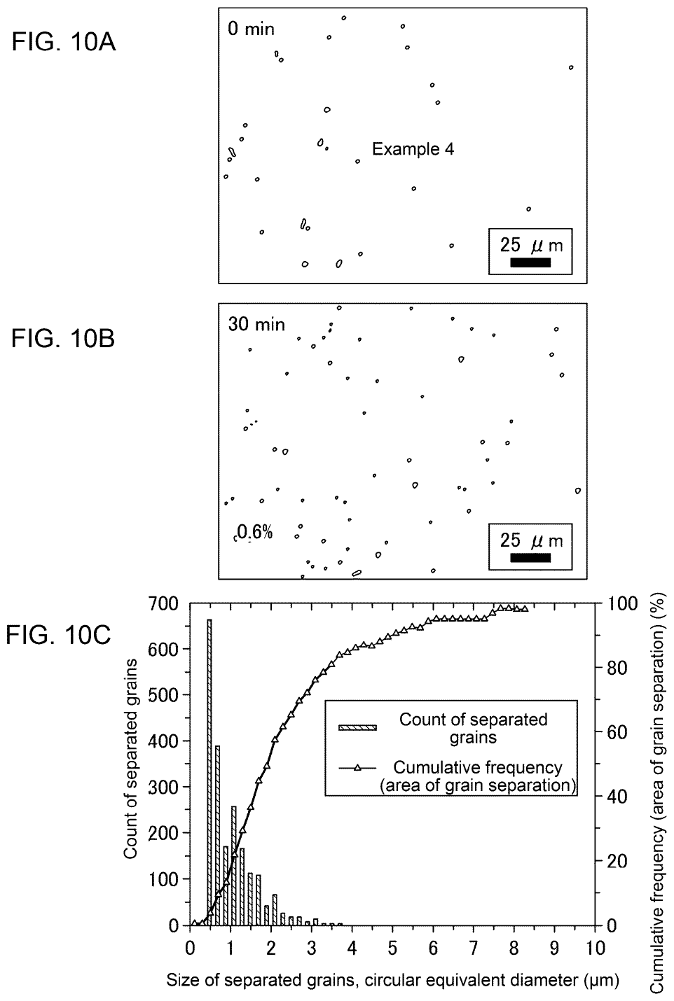

FIG. 10A is a diagram of an optical microscope image of the alumina sintered body (doped with 500 ppm of yttrium) before being polished. FIG. 10B is a diagram of an optical microscope image of the alumina sintered body (sample) after being polished. In the alumina sintered body (sample) after being polished illustrated in FIG. 10B, the likelihood of dust generation is 0.6%.

FIG. 10C is a graph indicating the results of the image analysis in the forced grain separation test. In FIG. 10C, the histogram indicates the relationship between the size of the separated grains (circular equivalent diameter, μm) and the number of separated grains (counts), and the line graph indicates the relationship between the size of the separated grains (circular equivalent diameter, μm) and the area ratio of grain separation (%).

### Comparative Example 1

To prepare the alumina slurry, 25 g of powder alumina was added to 500 ml of distilled water and stirred for 10 minutes at room temperature. An alumina sintered body (sample) was prepared in the same manner as in Example 1 except that the slurry was left at rest for 48 hours and concentrate obtained by removing supernatant of the slurry was lyophilized for 48 hours to prepare dry powder. The alumina sintered body (sample) was then evaluated. Table 1 indicates the results.

The alumina sintered body (sample) in Comparative Example 1 was doped with no yttrium. Thus, YAG was not detected. In Comparative Example 1, grain separation was notable due to wear of the alumina sintered body (sample). In addition, wear residuals occurred.

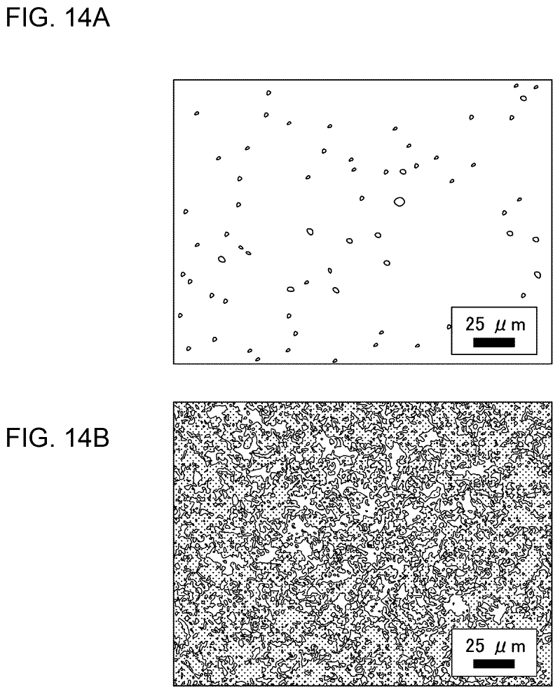

FIG. 12 is a diagram of an optical microscope image of the alumina sintered body (sample) in Comparative Example 1. FIG. 14A is a diagram of an optical microscope image of the alumina sintered body (doped with 0 ppm of yttrium) before being polished. FIG. 14B is a diagram of an optical microscope image of the alumina sintered body (sample) after being polished.

### Comparative Example 2

To prepare the alumina slurry, 46 g of powder alumina was added to 40 ml of distilled water and stirred for 10 minutes at room temperature. To prepare the mixed slurry of alumina and yttrium nitrate, 35 mg of yttrium nitrate was added to the alumina slurry and stirred for 10 minutes at room temperature. A solid content obtained through solid-liquid separation of the mixed slurry using a centrifuge was vacuum dried for 48 hours to prepare dry powder. An alumina sintered body (sample) was prepared in the same manner as in Example 1 except that the alumina sintered body (sample) doped with 4.5 ppm of yttrium with respect to the alumina polycrystal was obtained. The alumina sintered body (sample) was then evaluated. Table 1 indicates the results.

In the alumina sintered body (sample) in Comparative Example 2, YAG was detected, and thus yttrium may not be in the ionic state. In Comparative Example 2, grain separation was notable due to wear of the alumina sintered body (sample). In addition, wear residuals occurred.

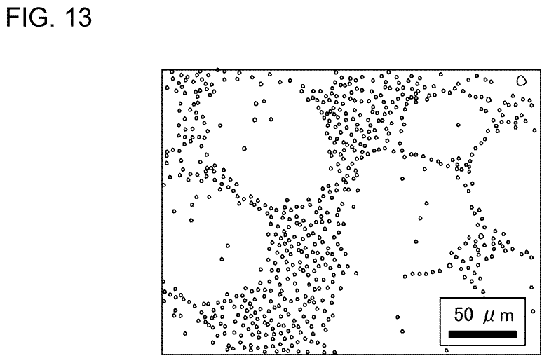

FIG. 13 is a diagram of an optical microscope image of the alumina sintered body (sample) in Comparative Example 2.

TABLE 1

| | Example | Example | Example | Example | Comparative | Comparative |
|---|---|---|---|---|---|---|
| | 1 | 2 | 3 | 4 | Example 1 | Example 2 |
| Forced grain | B | B | B | A | C | C |
| separation | | | | | | |
| test | | | | | | |
| Microstructure | B | B | A | A | B | C |
| analysis | | | | | | |
| Volume | 7.16E+15 | 1.15E+16 | 1.35E+16 | — | 8.50E+14 | — |
| resistivity | | | | | | |
| (Ωcm) | | | | | | |

As indicated in Table 1, the results of the forced grain separation test and the microstructure analysis are positive in Examples 1 to 4, and the volume resistivity exceeds 1.0×10¹⁵ in Examples 1 to 3. In contrast, in Comparative Example 1, the result of the forced grain separation test is negative, and the volume resistivity is less than 1.0×10¹⁵. In Comparative Example 2, the results of the forced grain separation test and the microstructure analysis are both negative.

These results reveal that the alumina ceramic member that contains alumina polycrystal with an average grain size less than or equal to 100 μm and is doped with yttrium in the state other than the crystalline state of an oxide, the crystalline state of a garnet structure, or the amorphous state, at the grain boundaries of the alumina polycrystal has a volume resistivity exceeding 1.0×10¹⁵ and reduces dust generation or grain separation due to friction.

Although the alumina ceramic member doped with yttrium at the grain boundaries of the alumina polycrystal has been described in the embodiments of the present disclosure, the alumina ceramic member may be doped with an element other than yttrium, and may be doped with a rare earth element having chemical properties similar to those of yttrium. Examples of such a rare earth element include erbium (Er), europium (Eu), cerium (Ce), and dysprosium (Dy).

The embodiments described above include, for example, the aspects described below.

### APPENDIX 1

An alumina ceramic member, comprising:
an alumina polycrystal with an average grain size less than or equal to 100 μm, wherein the alumina ceramic member is doped with yttrium in a state other than a crystalline state of an oxide, a crystalline state of a garnet structure, or an amorphous state, at grain boundaries of the alumina polycrystal.

### APPENDIX 2

The alumina ceramic member according to appendix 1, wherein the yttrium is in an ionic state.

### APPENDIX 3

The alumina ceramic member according to appendix 2, wherein
aluminum ions of the alumina polycrystal are selectively substituted by yttrium ions.

### APPENDIX 4

The alumina ceramic member according to any one of appendixes 1 to 3, wherein
a doping amount of the yttrium in the alumina polycrystal with an average grain size of 1 μm is 100 ppm or greater and 1000 ppm or less.

### APPENDIX 5

The alumina ceramic member according to any one of appendixes 1 to 4, wherein
a doping amount of the yttrium in the alumina polycrystal with an average grain size of 1 μm is 100 ppm or greater and 800 ppm or less.

### APPENDIX 6

The alumina ceramic member according to any one of appendixes 1 to 5, wherein
a doping amount of the yttrium in the alumina polycrystal with an average grain size of 10 μm is 10 ppm or greater and 100 ppm or less.

### APPENDIX 7

The alumina ceramic member according to any one of appendixes 1 to 6, wherein
a doping amount of the yttrium in the alumina polycrystal with an average grain size of 10 μm is 10 ppm or greater and 80 ppm or less.

### APPENDIX 8

The alumina ceramic member according to any one of appendixes 1 to 7, wherein
a doping amount of the yttrium in the alumina polycrystal with an average grain size of 100 μm is 1 ppm or greater and 10 ppm or less.

### APPENDIX 9

The alumina ceramic member according to any one of appendixes 1 to 7, wherein
a doping amount of the yttrium in the alumina polycrystal with an average grain size of 100 μm is 1 ppm or greater and 8 ppm or less.

### APPENDIX 10

The alumina ceramic member according to any one of appendixes 1 to 9, wherein
the alumina ceramic member has a volume resistivity greater than or equal to 1.0×10¹⁵ Ωcm at 200° C.

### APPENDIX 11

A method for manufacturing an alumina ceramic member, the alumina ceramic member containing an alumina polycrystal with an average grain size less than or equal to 100 μm, and being doped with yttrium in a state other than a crystalline state of an oxide, a crystalline state of a garnet structure, or an amorphous state, at grain boundaries of the alumina polycrystal, the method comprising:
adding alumina to an aqueous solution of yttrium and mixing the aqueous solution.

### APPENDIX 12

The method according to appendix 11, wherein
the yttrium is in an ionic state.

### APPENDIX 13

A component for a semiconductor manufacturing apparatus, comprising:
an alumina ceramic member, the alumina ceramic member containing an alumina polycrystal with an average grain size less than or equal to 100 μm, and being doped with yttrium in a state other than a crystalline state of an oxide, a crystalline state of a garnet structure, or an amorphous state, at grain boundaries of the alumina polycrystal.

### APPENDIX 14

The component according to appendix 13, wherein
the yttrium is in an ionic state.

### APPENDIX 15

The component according to appendix 13 or appendix 14, wherein
the component is an electrostatic chuck.

### APPENDIX 16

A substrate processing apparatus for processing a substrate, the apparatus comprising:
a substrate support having a substrate support surface to support the substrate,
wherein the substrate support includes an alumina ceramic member, and
the alumina ceramic member contains an alumina polycrystal with an average grain size less than or equal to 100 μm, and is doped with yttrium in a state other than a crystalline state of an oxide, a crystalline state of a garnet structure, or an amorphous state, at grain boundaries of the alumina polycrystal.

### APPENDIX 17

The substrate processing apparatus according to appendix 16, wherein
the yttrium is in an ionic state.

Although the embodiment of the disclosure has been described above, the disclosure is not limited to the embodiment, and may be modified or changed variously within the scope of the disclosure defined by the claims.

1. An alumina ceramic member, comprising:
an alumina polycrystal with an average grain size less than or equal to 100 μm,
wherein the alumina ceramic member is doped with yttrium in a state other than a crystalline state of an oxide, a crystalline state of a garnet structure, or an amorphous state, at grain boundaries of the alumina polycrystal.

2. The alumina ceramic member according to claim 1, wherein the yttrium is in an ionic state.

3. The alumina ceramic member according to claim 2, wherein aluminum ions of the alumina polycrystal are selectively substituted by yttrium ions.

4. The alumina ceramic member according to claim 1, wherein a doping amount of the yttrium in the alumina polycrystal with an average grain size of 1 μm is 100 ppm or greater and 1000 ppm or less.

5. The alumina ceramic member according to claim 1, wherein a doping amount of the yttrium in the alumina polycrystal with an average grain size of 1 μm is 100 ppm or greater and 800 ppm or less.

6. The alumina ceramic member according to claim 1, wherein a doping amount of the yttrium in the alumina polycrystal with an average grain size of 10 μm is 10 ppm or greater and 100 ppm or less.

7. The alumina ceramic member according to claim 1, wherein a doping amount of the yttrium in the alumina polycrystal with an average grain size of 10 μm is 10 ppm or greater and 80 ppm or less.

8. The alumina ceramic member according to claim 1, wherein a doping amount of the yttrium in the alumina polycrystal with an average grain size of 100 μm is 1 ppm or greater and 10 ppm or less.

9. The alumina ceramic member according to claim 1, wherein a doping amount of the yttrium in the alumina polycrystal with an average grain size of 100 μm is 1 ppm or greater and 8 ppm or less.

10. The alumina ceramic member according to claim 1, wherein the alumina ceramic member has a volume resistivity greater than or equal to 1.0×10¹⁵ Ωcm at 200° C.

11. A method for manufacturing an alumina ceramic member, the alumina ceramic member containing an alumina polycrystal with an average grain size less than or equal to 100 μm, and being doped with yttrium in a state other than a crystalline state of an oxide, a crystalline state of a garnet structure, or an amorphous state, at grain boundaries of the alumina polycrystal, the method comprising:
adding alumina to an aqueous solution of yttrium and mixing the aqueous solution.

12. The method according to claim 11, wherein the yttrium is in an ionic state.

13. A component for a semiconductor manufacturing apparatus, comprising:
an alumina ceramic member, the alumina ceramic member containing an alumina polycrystal with an average grain size less than or equal to 100 μm and being doped with yttrium in a state other than a crystalline state of an oxide, a crystalline state of a garnet structure, or an amorphous state, at grain boundaries of the alumina polycrystal.

14. The component according to claim 13, wherein the yttrium is in an ionic state.

15. The component according to claim 13, wherein the component is an electrostatic chuck.

16. A substrate processing apparatus for processing a substrate, the apparatus comprising:
a substrate support having a substrate support surface to support the substrate,
wherein the substrate support includes an alumina ceramic member, and
the alumina ceramic member contains an alumina polycrystal with an average grain size less than or equal to 100 μm, and is doped with yttrium in a state other than a crystalline state of an oxide, a crystalline state of a garnet structure, or an amorphous state, at grain boundaries of the alumina polycrystal.

17. The substrate processing apparatus according to claim 16, wherein the yttrium is in an ionic state.
